(19) United States
(12) Patent Application Publication
(10) Pub. No.: US 2024/0405740 A1
(43) Pub. Date: Dec. 5, 2024

(54) MULTI-TIER WAVE-FILTER AND ON-BOARD POWER SOURCE DCDC CONVERSION DEVICE

(71) Applicant: SHENZHEN VMAX NEW ENERGY (GROUP) CO. LTD., Shenzhen (CN)

(72) Inventors: Yingying FENG, Shenzhen (CN); Shun YAO, Shenzhen (CN); Ji LIU, Shenzhen (CN); Yao HE, Shenzhen (CN)

(21) Appl. No.: 18/797,779

(22) Filed: Aug. 8, 2024

Related U.S. Application Data
(63) Continuation of application No. PCT/CN2023/096103, filed on May 24, 2023.

(30) Foreign Application Priority Data
Oct. 10, 2022 (CN) 202211238276.4

(51) Int. Cl. H03H 1/00; H02M 1/14; H02M 1/32; H02M 3/155

(52) U.S. Cl. CPC H03H 1/00; H02M 1/14; H02M 1/32; H02M 3/155; H03H 2001/0085

(57) ABSTRACT

The present invention discloses a multi-tier wave-filter and an on-board power source DCDC conversion device. The multi-tier wave-filter includes: N-tiered PCB boards arranged at intervals, wherein N is greater than or equal to 3; N−1-level output inductors arranged at intervals, wherein an output inductor at each level is connected to adjacent upper-tier and lower-tier PCB boards through its input end and output end, respectively; N−1-level output capacitors arranged at intervals, wherein an output capacitor at each level is correspondingly connected to PCB boards between a second tier and a N^{th} tier, respectively; and a filter output terminal connected to an output end of the N−1-level output inductor. The multi-tier wave-filter provided by the present invention not only achieves miniaturizing the wave-filter and decreasing installation space, but also better enables the high-current path at the output end of the DCDC converter to have heat dissipation, filtering, shielding and other properties.

### CROSS-REFERENCE TO RELATED PATENT APPLICATION

This application is a continuation application of International Patent Application No. PCT/CN2023/096103, filed on May 24, 2023, which itself claims priority to Chinese Patent Application No. CN 202211238276.4 filed in China on Oct. 10, 2022. The disclosures of the above applications are incorporated herein in their entireties by reference.

### FIELD OF THE INVENTION

The present invention relates to the technical field of DCDC (Direct Current-Direct Current) converters, in particular to a multi-tier wave-filter and an on-board power source DCDC conversion device in which the wave-filter is applied.

### BACKGROUND OF THE INVENTION

The background description provided herein is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

A gradual increase of on-board intelligent devices with development of new energy automobile technology continually raises a demand for output power of on-board power DCDC conversion products; in addition, a gradual increase in need for miniaturization of on-board power DCDC conversion products makes it achievable to decrease installation space, so that an entire vehicle has more space to arrange these new smart devices, thereby improving intelligentization, integration and comfortability of new energy vehicles. However, even if the output power of on-board power DCDC conversion products increased, the output current would increase correspondingly, posing a higher challenge to design of high-current wave-filters at their output end.

As for the existing on-board power DCDC conversion products, the high-current wave-filters used at their output end adopt a single large-area monolithic PCB board, of which the output inductors and the output capacitors at each level are distributed on this monolithic PCB (Printed Circuit Board); therefore, on the one hand, this board occupies a large installation space, and on the other hand, the high current leads to current loss and coil heat, which influence operation states of the wave-filters.

Therefore, it is an urgent technical problem to be solved in this field to provide a miniaturized and high-current wave-filter suitable for output ends of on-board power DCDC conversion products.

### SUMMARY OF THE INVENTION

In order to solve the technical problem existing in the prior art, the invention provides a multi-tier wave-filter and an on-board power source DCDC conversion device in which the wave-filter is applied.

The technical scheme adopted in the present invention is to provides a multi-tier wave-filter comprising:
N-tiered PCB boards arranged at intervals from top to bottom, wherein N is greater than or equal to 3;
N−1-level output inductors arranged at intervals from top to bottom, wherein an output inductor at each level is connected to adjacent upper-tier and lower-tier PCB boards through its input end and output end, respectively;
N−1-level output capacitors arranged at intervals from top to bottom, wherein an output capacitor at each level is correspondingly connected to PCB boards between a second tier and a N^{th} tier, respectively; and
a filter output terminal connected to an output end of the N−1-level output inductor.

In an example, when N is equal to 3, an input end and an output end of a first-level output inductor are correspondingly connected to a first-tier PCB board and a second-tier PCB board, respectively; an input end and an output end of a second-level output inductor are correspondingly connected to the second-tier PCB board and a third-tier PCB board, respectively; a first-level output capacitor and a second-level output capacitor are correspondingly connected to the second-tier PCB board and the third-tier PCB board, respectively; the filter output terminal is connected to an output end of the second-level output inductor.

Preferably, the first-level output inductor includes a first magnetic core and at least two coils disposed inside the first magnetic core and connected in parallel with each other; a first input pin and a output pin are set on a top installation surface of the first magnetic core, and a terminal end of the first input pin away from the first magnetic core is higher than a terminal end of the output pin away from the first magnetic core; the first input pin and the output pin are correspondingly connected to the first-tier PCB board and the second-tier PCB board, respectively, and the top installation surface of the first magnetic core is set against a bottom surface of the second-tier PCB board;
the first-level output capacitor includes at least one first shell installed on the bottom surface of the second-tier PCB board and a capacitance component set inside the first shell;
the second-level output inductor includes a second magnetic core and a coil set inside the second magnetic core; a second input pin is set on a top end face of the second magnetic core, and an output copper flat-bar is set on a bottom end face of the second magnetic core; the second input pin and the output copper flat-bar are correspondingly connected to the second-tier PCB board and the third-tier PCB board, respectively;
the second-level output capacitor includes a second shell installed on a bottom surface of the third-tier PCB board and a capacitance component set inside the second shell;
the filter output terminal is connected to the output copper flat-bar.

In another example, when N is equal to 4, an input end and an output end of a first-level output inductor are correspondingly connected to a first-tier PCB board and a second-tier PCB board, respectively; an input end and an output end of a second-level output inductor are correspondingly connected to the second-tier PCB board and a third-tier PCB board, respectively; a first-level output capacitor and a second-level output capacitor are correspondingly connected to the second-tier PCB board and the third-tier PCB board, respectively; an input end and an output end of a third-level output inductor are correspondingly connected to the second-tier PCB board and the third-tier PCB board, respectively; an input end and an output end of a fourth-level output inductor are correspondingly connected to the third-tier PCB board and the second-tier PCB board, respectively; a fourth level output capacitor is connected to a fourth-tier PCB board, and the filter output terminal is connected to an output end of the third-level output inductor.
when N is equal to 3, a coil of the first-level output inductor is formed by way of winding a copper flat-bar into multi-turns, and the coil of the second-level output inductor is formed by winding a copper flat-bar into a single-turn.

Of the output copper flat-bar one end is connected to the bottom end face of the second magnetic core, and the other end is fixedly connected to the bottom end surface of the third-tier PCB board after passing through the third-tier PCB board, the first input pin passes through the second-tier PCB board, then is soldered to the first-tier PCB board, and the output pin and the second input pin are soldered to the second-tier PCB board.

Preferably, the filter output terminal includes an installation seat, an output port arranged at one end of the installation seat and a connection copper flat-bar arranged at the other end of the installation seat; an installation screw hole is set at the other end of the connection copper flat-bar, and a connection screw hole matching the installation screw hole is set at one end of the output copper flat-bar, thus the filter output terminal is connected to the output copper flat-bar by way of passing a fixing screw through the installation screw hole and the connection screw hole.

The present invention further provides an on-board power source DCDC conversion device, comprising a housing, and wave-filter being the multi-tier wave-filter, which is installed inside the housing.

Preferably, the housing forms a cavity used to isolate and shield inductance between a first-level output inductor and a second-level output inductor.

Preferably, a heat conduction part is mounted between the first-level output inductor as well as the second-level output inductor and the housing.

Compared with the prior art, the wave-filter provided by the present invention adopts a multi-tier PCB board, which not only achieves miniaturizing the wave-filter and decreasing installation space, but also better enables the high-current path at the output end of the DCDC converter to have heat dissipation, filtering, shielding and other properties. In addition, in view of the problem of decreasing large horizontal installation space, a flat copper bar is used for the coil of the inductor of the present invention, reducing current loss and coil heat, and raising inductance, so this design avoids the complex structural layout arising from heat dissipation and shielding demands.

### BRIEF DESCRIPTION OF THE DRAWINGS

In order to explain the technical solutions in the embodiments of the present invention or the prior art more clearly, the drawings needing to be used in the descriptions of the embodiments or the prior art are briefly introduced hereinafter. Obviously, the drawings in the following descriptions are only exemplary, and for those of ordinary skills in the art, other drawings may also be derived and obtained based on the provided drawings without going through any creative work.

FIG. 1 is a diagram of the full-bridge topology of the DCDC circuit in which the primary and secondary sides are isolated.

FIG. 2 is a diagram of the inductor used in the exampled multi-tier wave-filter in the present invention.

FIG. 3 is an entire structure diagram of the exampled multi-tier wave-filter in the present invention.

FIG. 4 is a diagram of the on-board power source DCDC conversion device used in the exampled multi-tier wave-filter in the present invention.

Reference numerals are as follows:

1—first-level output inductor; 11—first magnetic core; 12—first input pin; 13—output pin; 14—core seat; 2—first-tier PCB board; 3—second-tier PCB board; 31—first-level output capacitor; 311—first shell; 4—second-level output inductor; 41—filter output terminal; 411—installation seat; 412—output port; 413—connection copper flat-bar; 42—second magnetic core; 43—second input pin; 44—output copper flat-bar; 441—connection screw hole; 5—third-tier PCB board; 51—second-level output capacitor; 511—second shell; 7—primary side power switch transistor; 8—transformer; 9—secondary side switch transistor; 10—housing.

### DETAILED DESCRIPTION OF SOME EMBODIMENTS

In order to make the technical problem to be solved by the present invention, the technical solution and the beneficial effects clearer, we shall further describe the present invention in detail in combination with the drawings and examples. It should be understood that the specific examples described herein are only intended to explain the present invention and are not intended to pose a limitation on the present invention.

As shown in FIGS. 1-4, a multi-tier wave-filter provided by the present invention includes N-tiered PCB boards arranged at intervals from top to bottom, wherein N is greater than or equal to 3; N−1-level output inductors arranged at intervals from top to bottom, wherein an output inductor at each level is connected to adjacent upper-tier and lower-tier PCB boards through its input end and output end, respectively; N−1-level output capacitors arranged at intervals from top to bottom, wherein an output capacitor at each level is correspondingly connected to PCB boards between the second tier and the N^{th} tier, respectively; and a filter output terminal connected to an output end of the N−1-level output inductor.

FIG. 1 is a diagram of the full-bridge topology of the DCDC circuit in which the primary and secondary sides are isolated, including a primary side power switch transistor 7, a transformer 8, a secondary side switch transistor 9, a first-level output inductor 1, a first-level output capacitor 31, a second-level output inductor 4 and a second-level output capacitor 51. Because the DCDC output voltage is about 14V and the DCDC output power is more than 2-3 KW, the DCDC output current is generally relatively high, about 100-200 amp or even high. The wave-filter structure on the high-current path at the output side of the DCDC circuit topology designed by the present invention and shown in the dashed frame in FIG. 1, is composed of the first stage output inductor 1, the first-level output capacitor 31, the second-level output inductor 4 and the second-level output capacitor 51.

Referring to FIGS. 1-4 together, in Example 1 provided by the present invention, when the number N of tiers of the PCB boards is equal to 3, an input end and an output end of the first-level output inductor 1 are correspondingly connected to the first-tier PCB board 2 and the second-tier PCB board 3, respectively, so that a height difference is formed between the input end and an output end of the first-level output inductor 1. An input end and an output end of the second-level output inductor 4 are correspondingly connected to the second-tier PCB board 3 and the third-tier PCB board 5, respectively, so that a height difference is formed between the input end and an output end of the second-level output inductor 4. The first-level output capacitor 31 and the second-level output capacitor 51 are correspondingly connected to the second-tier PCB board 3 and the third-tier PCB board 5, respectively, and the filter output terminal 41 is connected to an output end of the second-level output inductor 4.

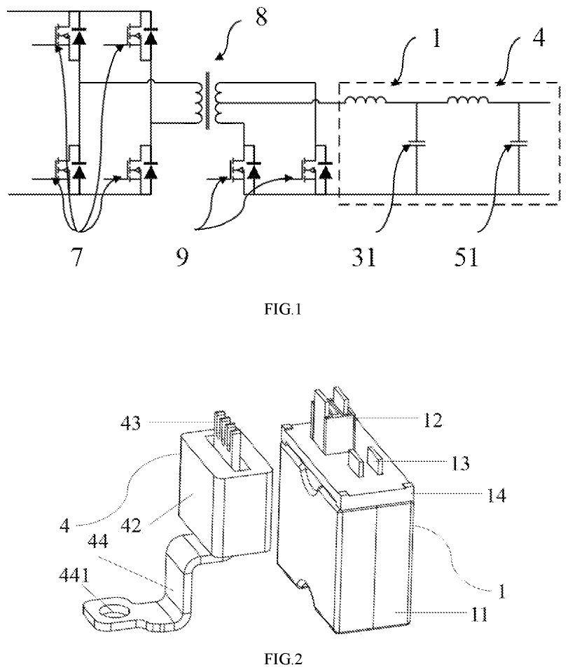

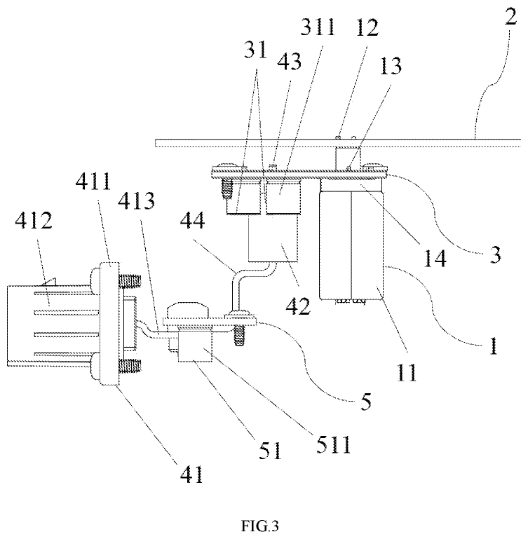

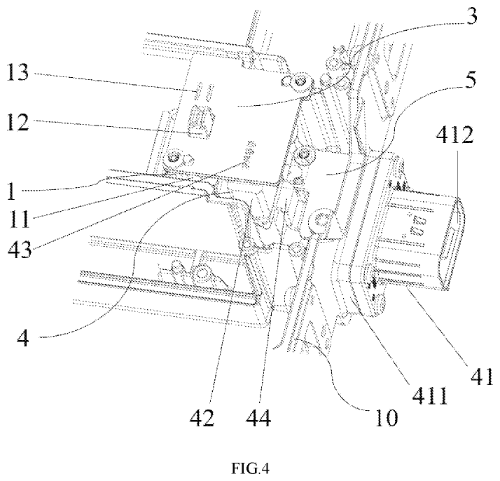

Referring to FIGS. 2-3, in this example, the first-level output inductor 1 includes a first magnetic core 11 and at least two coils disposed inside the first magnetic core 11 and connected in parallel with each other (not shown in the figures); a first input pin 12 and a output pin 13 are set on a top installation surface of the first magnetic core 11, and the terminal end of the first input pin 12 away from the first magnetic core 11 is higher than the terminal end of the output pin 13 away from the first magnetic core 11; the first input pin 12 and the output pin 13 are correspondingly connected to the first-tier PCB board 2 and the second-tier PCB board 3, respectively, and the top installation surface of the first magnetic core 11 is set against the bottom surface of the second-tier PCB board 3. A certain height difference, which can be soldered on the PCB boards at different tiers, is formed between the first input pin 12 and the output pin 13, and finally forms the complete first-level output inductor 1 together with the external first magnetic core 11 and a core seat 14 or a shell of the first magnetic core 11.

As a preferred embodiment, the two sets of coils connected in parallel of the first-level output inductor 1 are formed by way of winding a copper flat-bar into multi-turns, and the coil of the second-level output inductor 4 is formed by winding a copper flat-bar into a single-turn. Because the output current of DCDC is high, the copper flat-bar made of a flat copper strip forms the coil inside the first magnetic core 11, so as to abate current loss in the first-level output inductor 1 and reduce its heat generation. According to the analysis of the operation characteristics of components at each position in the circuit topology, a certain switching frequency current component occurs in the first-level output inductor 1, and in view of relative more capacity for the needed inductance, so a thin copper strip is winded into multi-turns to form a coil, which is used in parallel, so as to improve the inductance and reduce the skin effect. When an alternating current or an alternating electromagnetic field occurs in a conductor, the currents inside the conductor are unevenly distributed, thus they are concentrated in the “skin” part of the conductor; in other words, the currents are concentrated in the thin layer on the surface of the conductor, and the closer they approach the surface of the conductor, the greater the current density is, but the current level inside the conductor is actually low. As a result, the resistance of the conductor increases, so that its power loss also increases. This phenomenon is called the skin effect. Since the switching frequency current component in the second stage output inductor 4 is relatively small and can be basically ignored, and there is relatively less capacity for the needed inductance, the copper flat-bar is used to form a single-turn inductor coil.

Referring to FIGS. 2-3, in this example, the first-level output capacitor 31 includes at least one first shell 311 installed on the bottom surface of the second-tier PCB board 3 and a capacitance component set inside the first shell 311; as a preferred embodiment, the first-level output capacitor 31 includes two first shell 311 installed on the bottom surface of the second-tier PCB board 3.

Referring to FIGS. 2-3, in this example, the second-level output inductor 4 includes a second magnetic core 42 and a coil set inside the second magnetic core 42; a second input pin 43 is set on the top end face of the second magnetic core 42, and an output copper flat-bar 44 is set on the bottom end face of the second magnetic core 42; the second input pin 43 and the output copper flat-bar 44 are correspondingly connected to the second-tier PCB board 3 and the third-tier PCB board 5, respectively. According to actual demand on structure matching, the second input pin 43 and the output copper flat-bar 44 can form a flexible height difference and a matching mode to connect the front and rear levels, and the second magnetic core 42 enfolds the copper flat-bar to finally form the second-level output inductor 4.

In this example, the second-level output capacitor 51 includes a second shell 511 installed on the bottom surface of the third-tier PCB board 5 and a capacitance component set inside the second shell 511.

Referring to FIGS. 2-3, in this example, the filter output terminal 41 is connected to the output copper flat-bar 44 through a connection copper flat-bar 413. As a preferred embodiment, the output copper flat-bar 44 adopts a bending structure (the extension portions of the front and rear ends of the output copper flat-bar 44 are combined with each other to present a W shape), of the output copper flat-bar 44 one end is connected to the bottom end face of the second magnetic core 42, and the other end is fixedly connected to the bottom end surface of the third-tier PCB board 5 after passing through the third-tier PCB board 5. The first input pin 12 passes through the second-tier PCB board 3, then is soldered to the first-tier PCB board 2, and the output pin 13 and the second input pin 43 are soldered to the second-tier PCB board 3. In other examples, the output copper flat-bar 44 may also be L-shaped or in other shapes.

In this example, the filter output terminal 41 includes an installation seat 411, an output port 412 arranged at one end of the installation seat 411 and the connection copper flat-bar 413 arranged at the other end of the installation seat 411; an installation screw hole is set at the other end of the connection copper flat-bar 413 away from the installation seat 411, and a connection screw hole 441 matching the installation screw hole is set at one end of the output copper flat-bar 44, thus the filter output terminal 41 is threadedly connected to the output copper flat-bar 44 by way of passing a fixing screw through the installation screw hole and the connection screw hole 441.

In other embodiments, the above soldering mode and threaded connection can be replaced by conventional soldering, resistance welding, laser welding, screw connection, riveting connection and other modes according to details at the connection point.

In Example 2 provided by the present invention, when the number N of tiers of the PCB boards is equal to 4, an input end and an output end of the first-level output inductor 1 are correspondingly connected to the first-tier PCB board 2 and the second-tier PCB board 3, respectively; an input end and an output end of the second-level output inductor 4 are correspondingly connected to the second-tier PCB board 3 and the third-tier PCB board 5, respectively; the first-level output capacitor 31 and the second-level output capacitor 51 are correspondingly connected to the second-tier PCB board 3 and the third-tier PCB board 5, respectively, and the filter output terminal 41 is connected to an output end of the second-level output inductor 4, an input end and an output end of the third-level output inductor are correspondingly connected to the second-tier PCB board 3 and the third-tier PCB board 5, respectively; an input end and an output end of the fourth-level output inductor are correspondingly connected to the third-tier PCB board 5 and the second-tier PCB board 3, respectively; the fourth level output capacitor is connected to the fourth-tier PCB board, and the filter output terminal 41 is connected to an output end of the third-level output inductor.

In other examples, the number N of tiers of the PCB board may also be equal to or higher than 5 layers.

Referring to FIG. 4, the present invention also provides an on-board power source DCDC conversion device, including a housing 10, the above-mentioned multi-tier wave-filter installed inside the housing 10, and a power switch transistor, a transformer 8 and a secondary side switch transistor 9 connected to the first-tier PCB board 2 (the first-tier PCB board 2 in FIG. 4 has been hidden).

In this example, the housing 10 forms a (smaller) cavity used to isolate and shield inductance between the first-level output inductor 1 and the second-level output inductor 4 (periphery), so as to improve EMC filtering performance.

In this example, a heat conduction part is mounted between the first-level output inductor 1 as well as the second-level output inductor 4 and the housing 10, and the heat conduction part is preferably a heat conduction adhesive or a heat conduction pad, thus inductance heat can be conducted to the housing 10 through the heat conduction part for heat dissipation.

For the multi-tier wave-filter provided by the present invention, a single large-area monolithic PCB is split into N-tiered PCB boards arranged at intervals from top to bottom, and the output inductors at each level are distributed on each N-tiered PCB board; even if multiple PCBs are used to form a multi-level filter structure, and each inductor at each level of output inductance is arranged in parallel on each tiered circuit board; reasonably designing a height difference between each tiered circuit board and a connection mode therebetween conveniently achieves a high-current connection of the PCB at different levels with the inductance circuit between the front and rear levels, and avoids complexity and cost increase in a production process of wave-filters caused by adding additional metal products or other connecting means prone to high-current connection. The PCB board can also be differently tiered according to different needs to give a distinct number of tiers, so as achieve an optimal design of the number of tiers for the PCB board. A rational multi-tier structure achieves a high-performance and low-cost design while making the high-current filter compact and miniaturized.

The above content only acts as a better embodiment of the present invention, not used to pose any limitation on the present invention, and any modifications, equivalent substitutions, improvements and the likes made within the essence and principle of the present invention will fall within the protection scope of the present invention.

What is claimed is:

1. A multi-tier wave-filter comprising:
N-tiered PCB boards arranged at intervals from top to bottom, wherein Nis greater than or equal to 3;
N−1-level output inductors arranged at intervals from top to bottom, wherein an output inductor at each level is connected to adjacent upper-tier and lower-tier PCB boards through its input end and output end, respectively;
N−1-level output capacitors arranged at intervals from top to bottom, wherein an output capacitor at each level is correspondingly connected to PCB boards between a second tier and a N^{th} tier, respectively; and
a filter output terminal connected to an output end of the N−1-level output inductor.

2. The multi-tier wave-filter according to claim 1, wherein when N is equal to 3, an input end and an output end of a first-level output inductor are correspondingly connected to a first-tier PCB board and a second-tier PCB board, respectively; an input end and an output end of a second-level output inductor are correspondingly connected to the second-tier PCB board and a third-tier PCB board, respectively; a first-level output capacitor and a second-level output capacitor are correspondingly connected to the second-tier PCB board and the third-tier PCB board, respectively; the filter output terminal is connected to an output end of the second-level output inductor.

3. The multi-tier wave-filter according to claim 2, wherein the first-level output inductor comprises a first magnetic core and at least two coils disposed inside the first magnetic core and connected in parallel with each other; a first input pin and a output pin are set on a top installation surface of the first magnetic core, and a terminal end of the first input pin away from the first magnetic core is higher than a terminal end of the output pin away from the first magnetic core; the first input pin and the output pin are correspondingly connected to the first-tier PCB board and the second-tier PCB board, respectively, and the top installation surface of the first magnetic core is set against a bottom surface of the second-tier PCB board;
the first-level output capacitor comprises at least one first shell installed on the bottom surface of the second-tier PCB board and a capacitance component set inside the first shell;
the second-level output inductor comprises a second magnetic core and a coil set inside the second magnetic core; a second input pin is set on a top end face of the second magnetic core, and an output copper flat-bar is set on a bottom end face of the second magnetic core; the second input pin and the output copper flat-bar are correspondingly connected to the second-tier PCB board and the third-tier PCB board, respectively;
the second-level output capacitor comprises a second shell installed on a bottom surface of the third-tier PCB board and a capacitance component set inside the second shell;
the filter output terminal is connected to the output copper flat-bar.

4. The multi-tier wave-filter according to claim 1, wherein when N is equal to 4, an input end and an output end of a first-level output inductor are correspondingly connected to a first-tier PCB board and a second-tier PCB board, respectively; an input end and an output end of a second-level output inductor are correspondingly connected to the second-tier PCB board and a third-tier PCB board, respectively; a first-level output capacitor and a second-level output capacitor are correspondingly connected to the second-tier PCB board and the third-tier PCB board, respectively; an input end and an output end of a third-level output inductor are correspondingly connected to the second-tier PCB board and the third-tier PCB board, respectively; an input end and an output end of a fourth-level output inductor are correspondingly connected to the third-tier PCB board and the second-tier PCB board, respectively; a fourth level output capacitor is connected to a fourth-tier PCB board, and the filter output terminal is connected to an output end of the third-level output inductor.

5. The multi-tier wave-filter according to claim 3, wherein a coil of the first-level output inductor is formed by way of winding a copper flat-bar into multi-turns, and the coil of the second-level output inductor is formed by winding a copper flat-bar into a single-turn.

6. The multi-tier wave-filter according to claim 3, wherein of the output copper flat-bar (44) one end is connected to the bottom end face of the second magnetic core, and the other end is fixedly connected to the bottom end surface of the third-tier PCB board after passing through the third-tier PCB board, the first input pin (12) passes through the second-tier PCB board, then is soldered to the first-tier PCB board, and the output pin (13) and the second input pin (43) are soldered to the second-tier PCB board.

7. The multi-tier wave-filter according to claim 1, wherein the filter output terminal comprises an installation seat (411), an output port (412) arranged at one end of the installation seat and a connection copper flat-bar (413) arranged at the other end of the installation seat; an installation screw hole is set at the other end of the connection copper flat-bar, and a connection screw hole matching the installation screw hole is set at one end of the output copper flat-bar (44), thus the filter output terminal is connected to the output copper flat-bar by way of passing a fixing screw through the installation screw hole and the connection screw hole.

8. An on-board power source DCDC conversion device, comprising a housing, and wave-filter being the multi-tier wave-filter according to claim 2, which is installed inside the housing.

9. The on-board power source DCDC conversion device according to claim 8, wherein the housing forms a cavity used to isolate and shield inductance between a first-level output inductor and a second-level output inductor.

10. The on-board power source DCDC conversion device according to claim 8, wherein a heat conduction part is mounted between the first-level output inductor as well as the second-level output inductor and the housing.

11. An on-board power source DCDC conversion device, comprising a housing, and wave-filter being the multi-tier wave-filter according to claim 3, which is installed inside the housing.

12. The on-board power source DCDC conversion device according to claim 11, wherein the housing forms a cavity used to isolate and shield inductance between a first-level output inductor and a second-level output inductor.

13. The on-board power source DCDC conversion device according to claim 11, wherein a heat conduction part is mounted between the first-level output inductor as well as the second-level output inductor and the housing.
